(19) United States
(12) Patent Application Publication
(10) Pub. No.: US 2024/0290647 A1
(43) Pub. Date: Aug. 29, 2024

(54) Selective photo-induced transfer of good micro leds

(71) Applicant: ALEDIA, ÉCHIROLLES (FR)

(72) Inventors: Christophe LINCHENEAU, Moirans (FR); Nohora CAICEDO, Grenoble (FR); Julien MALCOIFFE, Grenoble (FR)

(21) Appl. No.: 18/564,825

(22) PCT Filed: May 24, 2022
(86) PCT No.: PCT/FR2022/050988

§ 371 Date: Nov. 28, 2023

(30) Foreign Application Priority Data
May 31, 2021 (FR) 21/05709

(51) Int. Cl. H01L 21/683; H01L 21/67; H01L 25/075

(52) U.S. Cl. CPC H01L 21/6835; H01L 21/67144; H01L 25/0753; H01L 2221/68322; H01L 2221/68381

(57) ABSTRACT

The invention relates to a handling member (3) for an optoelectronic device (1) capable of emitting light in a first wavelength range. said handling member (3) comprising a body having a selection layer (11) consisting of a photosensitive element that is configured to change its state locally when exposed to light radiation in the first wavelength range. The invention likewise relates to a method for handling an optoelectronic device (1), comprising:—a step (E4) of applying the selection layer (11) to the handling member (3) and/or to the at least one optoelectronic device (1):—a step (E5) of placing the handling member (3) in contact with the optoelectronic device (1) at the selection layer (11):—a step (E8) of supplying the optoelectronic device (1) with electrical energy. allowing the separation of the selection layer (11) and the optoelectronic device (1).

### TECHNICAL FIELD

The present disclosure concerns a member for manipulating at least one optoelectronic device.

The disclosure also concerns a method for manipulating such an optoelectronic device.

### BACKGROUND

In the field of light display screens, the light elements constituting the screen must be arranged in a matrix manner in an increasingly precise manner as the resolution of the screens increases. These light elements each comprise at least one light-emitting diode and are organized in the form of a multi-colored pixel or in the form of a monochrome sub-pixel.

It is known to produce the light-emitting diodes on an initial support in the form of a silicon or sapphire substrate and to transfer them to a receiving support different from the initial support and intended to constitute, after this transfer, the light display screen.

The transfer of a large quantity of light-emitting diodes between the initial support and the screen substrate raises numerous technical challenges. Indeed, the selection of a large number of diodes following a determined spacing at very short distances is complex and sometimes involves the use of techniques such as thermocompression which can lead to deterioration of the light-emitting diodes. Moreover, diodes can be naturally damaged in the general manufacturing process.

The mass transfer therefore sometimes involves the transfer of previously damaged diodes which are deposited on the screen and constitute black spots on the final device.

To resolve this problem, it is possible to repair or change the defective diodes. Although this method allows reducing the number of black spots, it involves additional manufacturing steps, which can increase costs and is tedious to implement.

### BRIEF SUMMARY

The present disclosure aims to propose a solution which responds to all or part of the aforementioned problems.

This aim can be achieved thanks to the implementation of a manipulating member capable of manipulating at least one optoelectronic device capable of emitting light in a first wavelength range, said manipulating member comprising a body having a contact surface, and a selection layer deposited on said contact surface, the selection layer consisting of a photosensitive element, said photosensitive element being configured to change state locally when it is subjected to a light radiation comprised in the first wavelength range, so as to vary between a first state in which the selection layer of the manipulating member adheres with the optoelectronic device, and a second state in which the selection layer of the manipulating member does not adhere with the optoelectronic device.

The arrangements previously described make it possible to propose a manipulating member configured to displace optoelectronic devices via the selection layer. The selection layer can moreover be removed when illuminated by the optoelectronic device.

The term «change of state», means a physical or chemical phenomenon which induces a structural or conformational change in the photosensitive element. For example, the change of state may correspond to a softening or hardening of the photosensitive element, or a change in solubility. The change of state can also correspond to a phase change of the photosensitive element. Thus, the photosensitive element can be configured to become liquid, or alternatively solid, or alternatively gaseous when it is subjected to a light radiation comprised in the first wavelength range, that is to say in particular when the optoelectronic device emits light. Alternatively, the photosensitive element can be configured to become labile when subjected to a light radiation comprised in the first wavelength range, that is to say in particular when the optoelectronic device emits light. Synergistically, if an optoelectronic device does not emit light, for example if it is damaged, it will not be able to emit a light radiation in the first wavelength range, and will therefore not be able to change state of the selection layer.

The manipulating member may further have one or more of the following characteristics, taken alone or in combination.

According to an embodiment, the photosensitive element is a molecular glue.

According to an embodiment, the photosensitive element is a photosensitive polymer. In this case, the change of state may comprise a change in solubility, either by partial or total polymerization, or by partial or total depolymerization, or by other mechanisms such as photocleavage, photoaddition, fragmentation, or other.

According to an embodiment, the photosensitive element is configured to change state locally when it is subjected to a light radiation comprised in the first wavelength range, so as to vary from the first state to the second state.

In other words, the photosensitive element is configured to allow the separation of the manipulating member and the optoelectronic device when it is subjected to a light radiation comprised in the first wavelength range.

According to an embodiment, the photosensitive element is configured to change state locally when it is subjected to a light radiation emitted by the optoelectronic device, so as to vary between the first state and the second state. This light radiation emitted by the optoelectronic device having a wavelength comprised in the first wavelength range.

Advantageously, the change in local state of the photosensitive element when it is subjected to a light radiation allows both to carry out an operating test of the optoelectronic device while allowing its detachment from the manipulating member, in just one step. It is therefore not necessary to carry out a test step to determine whether an optoelectronic device is defective before its transfer.

According to an embodiment, the second state is a liquid or labile state.

According to an embodiment, the contact surface of the body has contact pads intended to be brought into contact with said at least one optoelectronic device via the selection layer.

According to an embodiment, the contact pads are distributed on the contact surface according to a predetermined spacing corresponding to a spacing between two optoelectronic devices arranged on a sampling substrate.

According to an embodiment, the manipulating member comprises at least one cooperation notch having a shape allowing a nesting of the optoelectronic device, or having a complementary shape of the optoelectronic device. In this case, the manipulating member is configured to be able to nest with the optoelectronic device.

According to an embodiment, the manipulating member comprises a plurality of cooperation notches separated from each other by the predetermined spacing.

According to an embodiment, the predetermined spacing is defined as the spacing separating two optoelectronic devices on a receiving substrate receiving the optoelectronic devices after a manipulation from the sampling substrate by means of the manipulating member, in particular a substrate for a light display screen. For example, the predetermined spacing can be comprised between 50 um and 2 mm, and more particularly substantially equal to 100 um.

According to an embodiment, the manipulating member may comprise electronic tracks intended to be electrically connected with at least one electrode comprised in the optoelectronic device. For example, said at least one electrode may be a transparent conductive electrode (TCO) placed on a functional surface of the optoelectronic device, or an interconnection pad intended to be brought into contact with electronic connections arranged on the sampling substrate or the receiving substrate. Thus, and advantageously, the manipulating member can supply electrical energy to each optoelectronic device with which it is connected via the electronic tracks. In the case where the photosensitive element is a molecular glue, said supply of the optoelectronic device by the manipulating member can advantageously be carried out through the photosensitive element.

According to an embodiment, the first wavelength range is comprised between 190 nm and 2000 nm, more particularly between 365 nm and 800 nm, and is in particular substantially equal to 420 nm or substantially equal to 450 nm.

According to an embodiment, the optoelectronic device may comprise a light-emitting element comprising at least one light-emitting diode (LED) capable of emitting and/or capturing light, and optionally an electronic control component associated with said at least one light-emitting diode, such as a transistor. In particular, each diode may comprise a first doped part intended to be brought into contact with a first electrode, a second doped part intended to be brought into contact with a second electrode, and an active part capable of changing state when an outer parameter external to the active part is applied to the active part, the outer parameter may for example consist of the application of a current. The electronic control component is particularly capable of influencing at least one outer parameter associated with the active part. The electronic control component may for example be able to modulate at least one emission parameter relating to the light radiation likely to be emitted by the active part.

According to an embodiment, the photosensitive element may comprise an organic polymer belonging to the family of polythiophenes, or certain derivatives of methacrylate, or belonging to the family of acrylamides, siloxanes, polyphenylenes, polystyrenes, polyvinyl, polymers coordination, or equivalent. In general, the photosensitive polymer can be associated with a suitable photoinitiator such as DNQ (diazonaphthoquinone), complexes of ruthenium, Zinc iridium (RuBPy3-Tris (2,2′-bipyridine) of Ruthenium-, IrPPy3-Tris(2-phenylpyridine) of Iridium, ZNTPP-Zinc Tetraphenylporphyrin-), derivatives of organic fluorophores capable of forming a radical such as eosin, MPP (1-methyl-pyridinium phenyl), OBN (2-benzoylmethylenequinoline difluoroborate), DTC (7-(dimethylamino)-4,5-dihydronaphtho-thiophene-2-carbaldehyde), BODIPY (boron-dipyrromethene) derivatives, carbazole derivatives or equivalent.

According to an embodiment, the photosensitive element can be a positive resin such as siloxane resins, or polymethacrylate resins.

According to an embodiment, the photosensitive element may comprise a photoinitiator configured to harden the photosensitive element or to depolymerize it when it is subjected to a light radiation comprised in the first wavelength range.

The aim of the disclosure can also be achieved by implementing a method for manipulating at least one optoelectronic device from a sampling substrate, said at least one optoelectronic device being capable of emitting a light radiation comprised in a first wavelength range when supplied with electrical energy, the manipulating method comprising:
a step of supplying the sampling substrate on which the at least one optoelectronic device is arranged;
a step of providing a manipulating member comprising a body having a contact surface;
a step of applying a selection layer to at least one element selected from the group comprising said contact surface of the manipulating member and the at least one optoelectronic device, the selection layer consisting of a photosensitive element, said photosensitive element being configured to change state locally when it is subjected to a light radiation comprised in the first wavelength range;
a step of contacting the manipulating member with said at least one optoelectronic device at the level of the selection layer, so as to cause the manipulating member to adhere to the optoelectronic device;
a step of supplying said at least one optoelectronic device with electrical energy, involving the emission of a light radiation in the first wavelength range and the change in local state of the selection layer allowing the separation of the selection layer and the emitting optoelectronic device.

The arrangements previously described make it possible to propose a method for manipulating optoelectronic devices. The presence of the selection layer makes it possible in a first case to make the manipulating member adhere to the optoelectronic device, and in a second case to allow the separation of the optoelectronic device and the manipulating member.

The term «change of state», means a physical or chemical phenomenon which induces a structural or conformational change in the photosensitive element. For example, the change of state may correspond to a softening or hardening of the photosensitive element, or a change in solubility. The change of state can also correspond to a phase change of the photosensitive element. Thus, the photosensitive element can be configured to become liquid, or alternatively solid, or alternatively gaseous when it is subjected to a light radiation comprised in the first wavelength range, that is to say in particular when the optoelectronic device emits light. Alternatively, the photosensitive element can be configured to become labile when subjected to a light radiation comprised in the first wavelength range, that is to say in particular when the optoelectronic device emits light. Synergistically, if an optoelectronic device does not emit light, for example if it is damaged, it will not be able to emit a light radiation in the first wavelength range, and will therefore not be able to change state of the selection layer. The photosensitive element can further be configured to become liquid, or alternatively solid, or alternatively gaseous when it is subjected to a light radiation in the first wavelength range, that is to say in particular when the optoelectronic device emits light. Alternatively, the photosensitive element can be configured to become labile when it is subjected to a light radiation in the first wavelength range, that is to say in particular when the optoelectronic device emits light. Synergistically, if an optoelectronic device does not emit light, for example if it is damaged, it will not be able to emit light radiation in the first wavelength range, and will therefore not be able to change state of the selection layer. In this way, the manipulating method makes it possible to select defective optoelectronic devices on the surface of a screen substrate or those intended to emit light characterized by a wavelength which is not comprised in the first wavelength range.

The manipulating method may further have one or more of the following characteristics, taken alone or in combination.

According to an embodiment, the manipulating method comprises a step of removing the manipulating member, in which the manipulating member is separated from the sampling substrate.

According to an embodiment, the contacting step may comprise the application of a chemical or optical activation so as to increase the adhesion of the selection layer with the manipulating member and/or with the optoelectronic device. Thus, it can be planned that the implementation of optical activation is carried out by the emission of a light radiation comprised in a second wavelength range strictly different from the first wavelength range.

According to an embodiment, the manipulating method comprises a transfer phase from the sampling substrate to a receiving substrate, in particular a substrate for a display screen, implemented after the step of contacting the manipulating member, said transfer phase comprising:
a step of detaching said at least one optoelectronic device from the sampling substrate, in particular by mechanical traction applied to the body of the manipulating member; and
a positioning step in which the contact surface of the manipulating member is positioned opposite a receiving surface of the receiving substrate.

According to an embodiment, the positioning step is implemented so that the contact surface of the manipulating member is positioned facing a receiving surface of the receiving substrate, in a relative position such that the optoelectronic devices are in contact with the receiving surface of the receiving substrate.

According to an embodiment, the transfer phase is implemented before the step of supplying the electronic device.

According to an embodiment, the transfer phase is implemented after the step of supplying the electronic device.

According to an embodiment, the step of supplying electrical energy to the optoelectronic device is carried out before the step of detaching said at least one optoelectronic device from the sampling substrate.

According to an embodiment, the step of supplying electrical energy to the optoelectronic device makes it possible to place the optoelectronic device selectively in an emission mode in which it emits a light radiation in the first wavelength range and in an extinguishing mode in which it does not emit light radiation.

According to an embodiment, the sampling substrate comprises a plurality of optoelectronic devices, each optoelectronic device of the plurality of optoelectronic devices being able to be individually supplied with electrical energy.

According to an embodiment, the step of providing the sampling substrate comprises a provision of a light emitting screen substrate comprising a plurality of optoelectronic devices distributed over an emitting surface of the screen substrate, the emitting surface of the screen substrate comprising electronic connections configured to make it possible to individually supply each optoelectronic device of the plurality of optoelectronic devices, in particular during the step of supplying electrical energy.

According to an embodiment, the manipulating member comprises electronic tracks configured to enable each optoelectronic device of the plurality of optoelectronic devices to be individually supplied, in particular during the step of supplying electrical energy.

In this way, it is possible to individually supply the optoelectronic devices so as to cause the selection layer to change state. In other words, it is possible to selectively release each optoelectronic device from contact with the manipulating member. Thus, the arrangements previously described make it possible to individually select the optoelectronic devices to be manipulated with the manipulating member. For example, this may make it possible to remove only certain predetermined optoelectronic devices from the surface of the screen substrate.

According to an embodiment, the step of supplying electrical energy is implemented selectively on one or more of the optoelectronic devices of the plurality of optoelectronic devices.

In other words, the step of supplying electrical energy can be selectively applied to a set of optoelectronic devices selected from the plurality of optoelectronic devices, the number of optoelectronic devices of this set being greater than or equal to 1.

According to an embodimenvt, the step of supplying electrical energy is implemented on optoelectronic devices arranged relative to each other at a predetermined distance, in particular comprised between 50 um and 2 mm.

According to an embodiment, the manipulating method comprises a step of chemical treating the contact surface of the manipulating member to increase the chemical affinity of the manipulating member with the photosensitive element constituting the selection layer.

According to an embodiment, the chemical treatment step comprises exposing the contact surface to a plasma comprising dioxygen to generate hydroxyl bonds.

According to an embodiment, the chemical affinity can come from electrostatic interactions, or hydrophilic/hydrophobic interactions.

According to an embodiment, the chemical treatment step may comprise the starting of a polymerization reaction.

According to an embodiment, the step of removing the manipulating member may comprise a step in which the manipulating member is separated from the receiving substrate.

According to an embodiment, the step of removing the manipulating member can be implemented in a configuration where the manipulating member is arranged below the optoelectronic device in the direction of gravity. In this way when the photosensitive element is in the second state, and in particular if it is in a liquid, gaseous or labile state, it is detached from the optoelectronic device by simple gravity. In this way the photosensitive element is detached from the optoelectronic device by gravity, making it possible to not leave any residual material on the optoelectronic device during the step of removing the manipulating member.

### BRIEF DESCRIPTION OF THE DRAWINGS

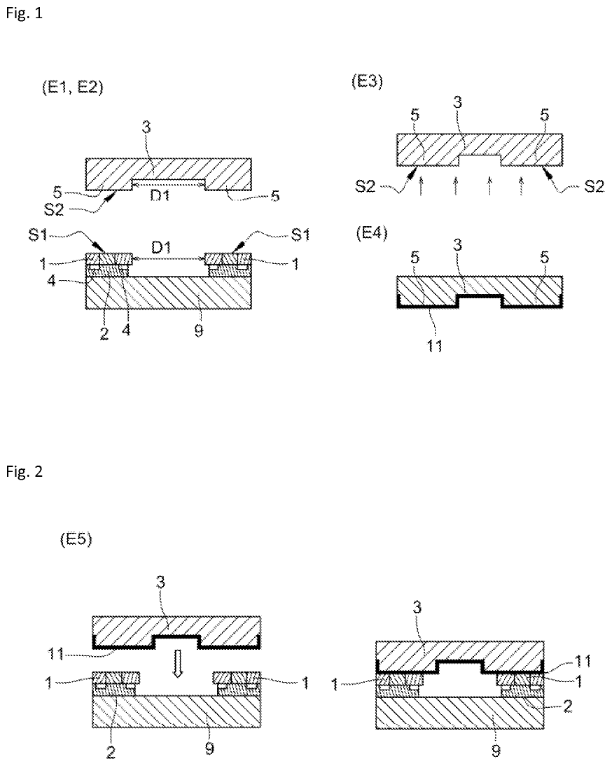

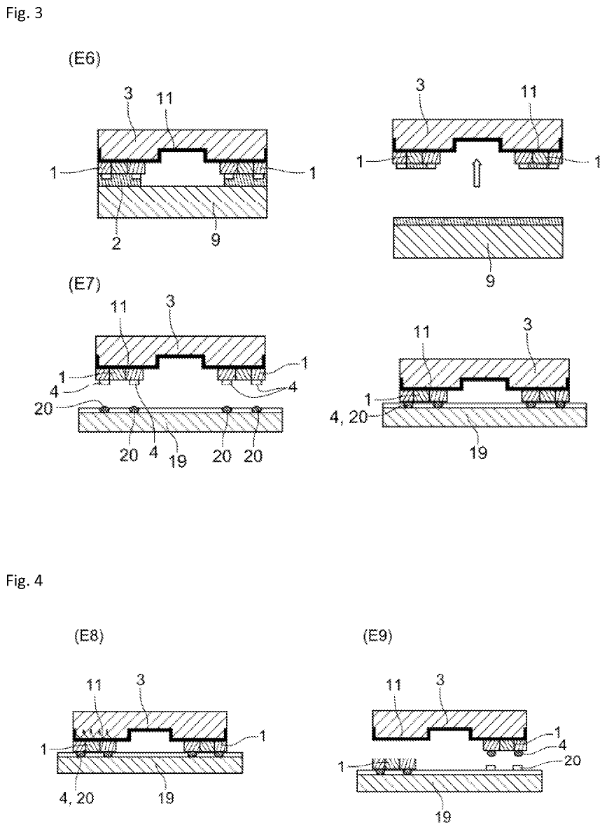

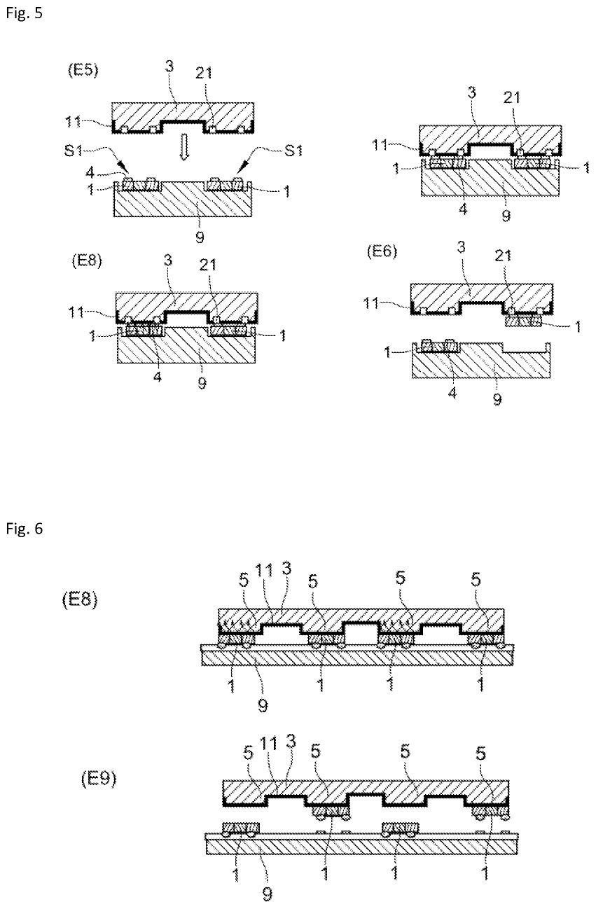

Other aspects, aims, advantages and characteristics of the disclosure will appear better on reading the following detailed description of preferred embodiments thereof, given by way of non-limiting example, and made with reference to the appended drawings in which:

[FIG. 1] FIG. 1 is a schematic view of certain steps of the manipulating method according to a particular embodiment of the disclosure.

[FIG. 2] FIG. 2 is a schematic view of certain steps of the manipulating method according to a particular embodiment of the disclosure.

[FIG. 3] FIG. 3 is a schematic view of certain steps of the manipulating method according to a particular embodiment of the disclosure.

[FIG. 4] FIG. 4 is a schematic view of certain steps of the manipulating method according to a particular embodiment of the disclosure.

[FIG. 5] FIG. 5 is a schematic view of certain steps of the manipulating method according to a particular embodiment of the disclosure.

[FIG. 6] FIG. 6 is a schematic view of certain steps of the manipulating method according to a particular embodiment of the disclosure.

### DETAILED DESCRIPTION

In the figures and in the remainder of the description, the same references represent identical or similar elements. In addition, the different elements are not represented to scale so as to favor the clarity of the figures. Furthermore, the different embodiments and variants are not exclusive of each other and can be combined with each other.

As illustrated in FIGS. 1 to 6, the disclosure firstly concerns a manipulating member 3 capable of manipulating at least one optoelectronic device 1 capable of emitting light in a first wavelength range, and also a method for manipulating such an optoelectronic device 1 from a sampling substrate 9. In general, the optoelectronic device 1 is intended to be fixed on a receiving face of a receiving substrate 19, such as for example a substrate for a light display screen, in particular by means of a surface distribution of a plurality of such optoelectronic devices 1 on all or part of the free surface of the receiving face. In general, and as shown in FIGS. 1 to 3, each optoelectronic device 1 can be attached to the sampling substrate 9 via an adhesion layer 2. Alternatively, and as shown in FIG. 5, the optoelectronic devices 1 can simply be deposited on the sampling substrate 9, for example constituted by a sampling tray. The optoelectronic devices 1 may have at least one interconnection pad 4 intended to cooperate with electronic connections 20 arranged on the surface of the receiving substrate 19. For example, each interconnection pad 4 may be intended to be soldered to an electronic connection 20. Alternatively, the interconnection pads 4 can be intended to cooperate with electronic tracks 21 comprised on the manipulating member 3, so that the manipulating member 3 can supply electrical energy to the optoelectronic devices 1 to which it is electrically connected.

According to an embodiment, the optoelectronic device 1 may comprise a light-emitting element comprising at least one light-emitting diode (LED) capable of emitting and/or capturing light, and optionally an electronic control component associated with said at least one light-emitting diode, such as a transistor. In particular, each diode may comprise a first doped part intended to be brought into contact with a first electrode, a second doped part intended to be brought into contact with a second electrode, and an active part capable of changing state when an outer parameter external to the active part is applied to the active part, the outer parameter may for example consist of the application of a current. The electronic control component is particularly capable of influencing at least one outer parameter associated with the active part. The electronic control component may for example be able to modulate at least one emission parameter relating to the light radiation likely to be emitted by the active part.

With reference to FIG. 1, the manipulating member 3 comprises a body having a contact surface S2 on which is deposited a selection layer 11 consisting of a photosensitive element. The body may in particular have contact pads 5 at the level of the contact surface S2, intended to be brought into contact with said at least one optoelectronic device 1 via the selection layer 11. The contact pads 5 may be distributed on the contact surface S2 according to a predetermined spacing D1 corresponding to a spacing between two optoelectronic devices 1 arranged on a sampling substrate 9.

According to another non-shown embodiment, the manipulating member 3 comprises at least one cooperation notch having a shape allowing a nesting of the optoelectronic device 1, or having a complementary shape of the optoelectronic device 1. In this case, the manipulating member 3 is configured to be able to nest with the optoelectronic device 1. For example, the manipulating member 3 can comprise a plurality of cooperation notches separated from each other by the predetermined spacing D1.

It may in particular be provided that the predetermined spacing D1 is defined as the spacing separating two optoelectronic devices 1 on a receiving substrate 19 receiving the optoelectronic devices 1 after a manipulation from the sampling substrate 9 by means of the manipulating member 3, in particular a substrate for a light display screen. For example, the predetermined spacing D1 can be comprised between 50 μm and 2 mm, and more particularly substantially equal to 100 μm.

According to an embodiment, the manipulating member 3 may comprise electronic tracks 21 intended to be electrically connected with at least one electrode comprised in the optoelectronic device 1. For example, said at least one electrode may be a transparent conductive electrode (TCO) arranged on a functional surface S1 of the optoelectronic device 1, or one of the interconnection pads 4 intended to be in contact with the electronic connections 20 arranged on the sampling substrate 9 or the receiving substrate 19. Thus, and advantageously, the manipulating member 3 can supply electrical energy to each optoelectronic device 1 with which it is connected via the electronic tracks 21. In the case where the photosensitive element is a molecular glue, said supply of the optoelectronic device 1 by the manipulating member 3 can be produced through the photosensitive element. Thus, and advantageously, the photosensitive element is not likely to produce light interference, or interact with the light radiation generated by the optoelectronic device 1.

As indicated previously, the selection layer 11 consists of the photosensitive element, said photosensitive element being configured to change state locally when it is subjected to a light radiation comprised in a first wavelength range, so as to vary between a first state in which the selection layer 11 of the manipulating member 3 adheres with the optoelectronic device 1, and a second state in which the selection layer 11 of the manipulating member 3 does not adhere with the optoelectronic device 1. For example, the photosensitive element is configured to change state locally when it is subjected to a light radiation comprised in the first wavelength range, so as to vary from the first state to the second state. In other words, the photosensitive element is configured to allow the separation of the manipulating member 3 and the optoelectronic device 1 when it is subjected to a light radiation comprised in the first wavelength range. More particularly, the photosensitive element can be configured to change state locally when it is subjected to a light radiation emitted by the optoelectronic device 1, so as to vary between the first state and the second state. This light radiation emitted by the optoelectronic device 1 having a wavelength comprised in the first wavelength range. Thus, and advantageously, the change in local state of the photosensitive element when it is subjected to a light radiation allows both to carry out a functional test of the optoelectronic device 1 while allowing its detachment from the manipulating member 3, in a single step. It is therefore not necessary to carry out a test step to determine whether an optoelectronic device 1 is defective before its transfer.

The term «change of state», means a physical or chemical phenomenon which induces a structural or conformational change in the photosensitive element. For example, the change of state may correspond to a softening or hardening of the photosensitive element. The change of state can also correspond to a change in phase of the photosensitive element. Thus, the photosensitive element can be configured to become liquid, or alternatively solid, or alternatively gaseous when it is subjected to a light radiation in the first wavelength range, that is to say in particular when the optoelectronic device 1 emits light. Alternatively, the photosensitive element can be configured to become labile when subjected to a light radiation in the first wavelength range, that is to say in particular when the optoelectronic device 1 emits light. Synergistically, if an optoelectronic device 1 does not emit light, for example if it is damaged, it will not be able to emit a light radiation at the first wavelength range, and will therefore not be able to change the state of the selection layer 11.

According to another embodiment, the photosensitive element may comprise a photosensitive polymer. In this case, the change of state may also comprise a change in solubility, either by partial or total polymerization, or by partial or total depolymerization, or by other mechanisms such as photocleavage, photoaddition, fragmentation, or other. For example, the photosensitive element can be a positive resin such as siloxane resins, polymethacrylates, or a family of polymers presenting a radical polymerization mechanism or RAFT (Reversible Addition-Fragmentation chain Transfer) type, or other polymers such as acrylamides or polyphenylenes.

According to an embodiment, the photosensitive polymer may comprise a photoinitiator configured to harden the photosensitive polymer or to depolymerize it when it is subjected to a light radiation comprised in the first wavelength range. In particular, the first wavelength range can be comprised between 190 nm and 2000 nm, more particularly between 365 nm and 800 nm and is in particular substantially equal to 420 nm or substantially equal to 450 nm.

The arrangements previously described make it possible to propose a manipulating member 3 configured to displace optoelectronic devices 1 via the selection layer 11. The selection layer 11 can also be removed when it is illuminated by the optoelectronic device 1.

As indicated previously, the disclosure also concerns a method for manipulating at least one optoelectronic device 1 from a sampling substrate 9, and preferably intended to be fixed on a receiving face of a receiving substrate 19, such as for example a substrate for a light display screen, being distributed over all or part of the free surface of the receiving face.

With reference to FIG. 1, the manipulating method comprises a step E1 of providing the sampling substrate 9 on which the at least one optoelectronic device 1 is arranged. For example, the sampling substrate 9 may comprise a plurality of optoelectronic devices 1 arranged on the surface of the sampling substrate 9 according to a first spacing D1. According to a non-limiting variant, the optoelectronic devices 1 can have dimensions comprised between 1 μm and 1 mm. Moreover, the distance between optoelectronic devices 1 on the receiving face of the receiving substrate 19 is comprised between 1 μm and 2 mm. Each optoelectronic device 1 has a functional surface S1 and is capable of emitting light radiation comprised in a first wavelength range by this functional surface S1 when supplied with electrical energy. The manipulating method also comprises a step E2 of providing a manipulating member 3 comprising a body having a contact surface S2, for example of the type of one of those described above. Subsequently, a step E3 of chemical treating the contact surface S2 of the manipulating member 3 can be implemented to increase the chemical affinity of the manipulating member 3 with a photosensitive element configured to form a selection layer 11 during a step E4 of applying a selection layer 11. Alternatively or jointly, the chemical surface treatment step E3 can be applied to the functional surface S1 of the optoelectronic device 1. According to a first non-limiting variant, the chemical treatment step E3 comprises the exposure of the contact surface S2 or the functional surface S1 to a plasma comprising dioxygen to generate hydroxyl bonds. According to a second non-limiting variant, the chemical affinity can come from electrostatic interactions, hydrophilic/hydrophobic interactions, Van der Waals interactions, or any type of weak or strong interaction. Finally, according to a third non-limiting variant, the chemical treatment step E3 may comprise the start of a polymerization reaction, comprising for example the formation of radicals on the surface, to initiate the polymerization reaction.

The method then comprises said step E4 of applying the selection layer 11 to at least one element selected from the group comprising said contact surface S2 of the manipulating member 3 and the at least one optoelectronic device 1. The selection layer 11 consists of a photosensitive element configured to change state locally when it is subjected to a light radiation in the first wavelength range.

In the same way as above, by «change of state», is meant a physical or chemical phenomenon which induces a structural or conformational change of the photosensitive element constituting the selection layer 11. For example, the change of state can correspond to a softening or hardening of the photosensitive element. The change of state may also comprise a change in solubility either by partial or total depolymerization, or by other mechanisms such as photocleavage, photoaddition, fragmentation, or other. The change of state can also correspond to a phase change of the photosensitive element. Thus, the photosensitive element can be configured to become liquid when it is subjected to a light radiation at the first wavelength range, that is to say in particular when the optoelectronic device 1 emits light. Alternatively, the photosensitive element can be configured to become labile when subjected to a light radiation at the first wavelength range, that is to say in particular when the optoelectronic device 1 emits light.

With reference to FIG. 2, the manipulating member 3 is secured to the optoelectronic device 1 during a step E5 of contacting the manipulating member 3 with said at least one optoelectronic device 1 at the level of the selection layer 11. In this way the manipulating member 3 adheres with the optoelectronic device 1. Advantageously, the contacting step E5 can comprise the application of a chemical or optical activation so as to increase the adhesion of the selection layer 11 with the manipulating member 3 and/or with the optoelectronic device 1. Thus, it can be provided that the implementation of optical activation is carried out by the emission of a light radiation comprised in a second wavelength range strictly different from the first wavelength range.

As illustrated in FIG. 3, the manipulating method can comprise a phase of transferring the optoelectronic device from the sampling substrate 9 to a receiving substrate 19, in particular a substrate for a display screen. This transfer phase can be implemented after the step E5 of contacting the manipulating member 3.

The transfer phase may firstly comprise a step E6 of detaching said at least one optoelectronic device 1 from the sampling substrate 9, in particular by mechanical traction applied to the body of the manipulating member 3. Then, the transfer phase may comprise a positioning step E7 in which the contact surface S2 of the manipulating member 3 is positioned opposite a receiving surface of the receiving substrate 19, for example in a relative position such that the optoelectronic devices 1 are in contact with the receiving surface of the receiving substrate 19. The positioning step E7 may in particular comprise the cooperation of each interconnection pad 4 with electronic connections 20 arranged on the surface of the receiving substrate 19, for example by soldering. Advantageously, alignment elements, such as for example alignment marks associated with optical devices or lasers, can be provided to allow the installation of the optoelectronic devices 1 on the receiving face of the receiving substrate 19.

With reference to FIGS. 4 to 6, the manipulating method further comprises a step E8 of supplying said at least one optoelectronic device 1 with electrical energy, involving the emission of a light radiation in the first wavelength range and the change of local state of the selection layer 11 allowing the separation of the selection layer 11 and the emitting optoelectronic device 1. Generally, the supply step E8 is implemented after the contacting step E5.

According to a first variant shown in FIG. 4, the step E8 of supplying electrical energy to the optoelectronic device 1 is implemented after the transfer phase. In this case, during the step E6 of detaching said at least one optoelectronic device 1 from the sampling substrate 9, all the optoelectronic devices 1 are detached from the sampling substrate 9.

According to a second variant shown in FIG. 5, the step E6 of detaching said at least one optoelectronic device 1 from the sampling substrate 9 can be implemented after the supply step E8. According to this first variant, the step E8 of supplying electrical energy to the optoelectronic device 1 is therefore implemented before the transfer phase. In this case, during the step E6 of detaching said at least one optoelectronic device 1 from the sampling substrate 9, only the optoelectronic devices 1 which have not emitted light radiation in the first wavelength range are detached from the sampling substrate 9. Thus, the manipulating method makes it possible to remove from the sampling substrate 9 the non-emitting optoelectronic devices 1, such as the defective optoelectronic devices 1. Alternatively, the manipulating method makes it possible to remove from the sampling substrate 9, the optoelectronic devices 1 emitting light radiation which is not comprised in the first wavelength range. Thus, the optoelectronic devices 1 detached during the detachment step E6 are not transferred during the transfer phase but are simply evacuated because these optoelectronic devices 1 are not operated.

According to a third variant shown in FIG. 6, the sampling substrate 9 can comprise a plurality of optoelectronic devices 1, where each optoelectronic device 1 of the plurality of optoelectronic devices 1 can be individually supplied with electrical energy. For example, the step E1 of providing the sampling substrate 9 may comprise the provision of a light emitting screen substrate comprising a plurality of optoelectronic devices 1 distributed over an emitting surface of the screen substrate, the emission surface of the screen substrate can advantageously have electronic connections 20 configured to enable each optoelectronic device 1 of the plurality of optoelectronic devices 1 to be individually supplied. In particular, the step EB of supplying electrical energy to the optoelectronic device 1 can make it possible to place the optoelectronic device 1 selectively in an emission mode in which it emits a light radiation in the first wavelength range and in an extinguishing mode in which it does not emit a light radiation. In this way, it is possible to individually supply the optoelectronic devices 1 so as to cause the selection layer 11 to change state. The electrical energy supply step E8 can therefore be implemented selectively on one or more of the optoelectronic devices 1 of the plurality of optoelectronic devices 1.

Whatever the implemented embodiment, the arrangements previously described make it possible to selectively release each optoelectronic device 1 from contact with the manipulating member 3. Thus, it is possible to individually select the optoelectronic devices 1 to be manipulated with the manipulating member 3. For example, this can make it possible to remove only certain predetermined optoelectronic devices 1 from the surface of the sampling substrate. For example, the step E8 of supplying electrical energy can be applied selectively to a set of optoelectronic devices 1 selected from the plurality of optoelectronic devices, the number of optoelectronic devices 1 of this set being greater than or equal to 1. For example, the step E8 of supplying electrical energy can be implemented on optoelectronic devices 1 arranged relative to each other at a predetermined distance, in particular comprised between 50 μm and 2 mm.

Finally, the manipulating method comprises a step E9 of removing the manipulating member 3, in which the manipulating member 3 is separated from the sampling substrate 9, or from the receiving substrate 19.

The arrangements previously described make it possible to propose a method for manipulating optoelectronic devices 1. The presence of the selection layer 11 makes it possible in a first case to make the manipulating member 3 adhere to the optoelectronic device 1, and in a second case to allow the separation of the optoelectronic device 1 and the manipulating member 3. Advantageously, the photosensitive element is configured to become labile when it is subjected to a light radiation comprised in the first wavelength range, that is to say in particular when the optoelectronic device 1 emits light.

Thus, the manipulating method can make it possible to carry out a transfer of an optoelectronic device 1 from a sampling substrate 9 to a receiving substrate 19, such as a screen substrate or a test substrate, thanks to a reversible adhesion between the manipulating member 3 and the optoelectronic device 1 via the selection layer 11.

Alternatively, the manipulating method can make it possible to remove from a sampling substrate 9, such as a screen substrate or a test substrate, optoelectronic devices 1 not emitting light radiation in the first wavelength range. This can in particular make it possible to remove defective optoelectronic devices 1 from a sampling substrate 9.

1. A manipulating member capable of manipulating at least one optoelectronic device capable of emitting light in a first wavelength range, said manipulating member comprising a body having a contact surface, and a selection layer deposited on said contact surface, the selection layer consisting of comprising a photosensitive element, said photosensitive element being configured to change state locally when it is subjected to a light radiation comprised in the first wavelength range, so as to vary between a first state in which the selection layer of the manipulating member adheres with the optoelectronic device, and a second state in which the selection layer of the manipulating member does not adhere with the optoelectronic device.

2. The manipulating member according to claim 1, wherein the contact surface of the body has contact pads intended to be in contact with said at least one optoelectronic device via the selection layer.

3. The manipulating member according to claim 2, wherein the contact pads are distributed on the contact surface according to a predetermined spacing corresponding to a spacing between two optoelectronic devices arranged on a sampling substrate.

4. The manipulating member according to claim 1, wherein the first wavelength range is comprised between 190 nm and 2000 nm, more particularly between 365 nm and 800 nm, and is in particular substantially equal to 420 nm or substantially equal to 450 nm.

5. A method for manipulating at least one optoelectronic device from a sampling substrate, said at least one optoelectronic device being capable of emitting a light radiation comprised in a first wavelength range when supplied with electrical energy, the manipulating method comprising:
a step of providing the sampling substrate on which the at least one optoelectronic device is arranged;
a step of providing a manipulating membercomprising a body having a contact surface;
a step of applying a selection layer on at least one element selected from the group comprising said contact surface of the manipulating member and the at least one optoelectronic device, the selection layer comprising a photosensitive element, said photosensitive element being configured to change state locally when it is subjected to a light radiation comprised in the first wavelength range;
a step of contacting the manipulating member with said at least one optoelectronic device at the level of the selection layer, so as to make the manipulating member adhere with the optoelectronic device;
a step of supplying said at least one optoelectronic device with electrical energy, involving the emission of a light radiation in the first wavelength range and the change in local state of the selection layer allowing the separation of the selection layer and the emitting optoelectronic device.

6. The manipulating method according to claim 5, comprising a step of removing the manipulating member, wherein the manipulating member is separated from the sampling substrate

7. The manipulating method according claim 5, comprising a transfer phase from the sampling substrate to a receiving substrate, in particular a substrate for a display screen, implemented after the step of contacting the manipulating member, said transfer phase comprising:
a step of detaching said at least one optoelectronic device from the sampling substrate, in particular by mechanical traction applied to the body of the manipulating member; and
a positioning step in which the contact surface of the manipulating member is positioned opposite a receiving surface of the receiving substrate.

8. The manipulating method according to claim 7, wherein the positioning step is implemented so that the contact surface of the manipulating member is positioned facing a receiving surface of the receiving substrate, in a relative position such that the optoelectronic devices are in contact with the receiving surface of the receiving substrate.

9. The manipulating method according to any one of claim 7, wherein the step of supplying electrical energy to the optoelectronic device is carried out before the step of detaching said at least one optoelectronic device from the sampling substrate.

10. The manipulating method according to claim 5, wherein the step of supplying electrical energy to the optoelectronic device makes it possible to place the optoelectronic device selectively in an emission mode in which it emits a light radiation in the first wavelength range and in an extinguishing mode in which it does not emit light radiation.

11. The manipulating method according to claim 5, wherein the sampling substrate comprises a plurality of optoelectronic devices, each optoelectronic device of the plurality of optoelectronic devices being able to be individually supplied with electrical energy.

12. The manipulating method according to claim 11, wherein the step of supplying electrical energy is implemented selectively on one or more of the optoelectronic devices of the plurality of optoelectronic devices.

13. The manipulating method according to claim 12, wherein the step of supplying electrical energy is implemented on optoelectronic devices arranged relative to each other at a predetermined distance, in particular comprised between 50 μm and 2 mm.

14. The manipulating method according to any one of claim 5, comprising a step of chemical treating the contact surface of the manipulating member to increase the chemical affinity of the manipulating member with the photosensitive element constituting the selection layer.

15. The manipulating method according to claim 5, wherein the step of providing the sampling substrate comprises the provision of a light emitting screen substrate comprising a plurality of optoelectronic devices distributed over an emitting surface of the screen substrate, the emitting surface of the screen substrate comprising electronic connections configured to make it possible to individually supply each optoelectronic device of the plurality of optoelectronic devices, in particular during the step of supplying electrical energy.

16. The manipulating method according to claim 5, wherein the manipulating member comprises electronic tracks configured to allow supplying each optoelectronic device of the plurality of optoelectronic devices, in particular during the step of supplying electrical energy.
